(19) United States
(12) Patent Application Publication
(10) Pub. No.: US 2026/0247626 A1
(43) Pub. Date: Aug. 20, 2026

(54) SEMICONDUCTOR MEMORY DEVICE AND METHOD FOR FABRICATING THE SAME

(71) Applicant: Samsung Electronics Co., Ltd., Suwon-si (KR)

(72) Inventors: Young In Goh, Suwon-si (KR); Kil Ho Lee, Suwon-si (KR); Seo Ha Lee, Suwon-si (KR)

(21) Appl. No.: 19/369,560

(22) Filed: Oct. 27, 2025

(30) Foreign Application Priority Data
Feb. 18, 2025 (KR) 10-2025-0020577

(51) Int. Cl. H10B 51/30; H10B 51/20

(52) U.S. Cl. CPC H10B 51/30; H10B 51/20

(57) ABSTRACT

A semiconductor memory device and method are provided with enhanced performance and a simplified process. The semiconductor memory device includes a substrate, a stacked structure on the substrate, including a plurality of conductive patterns spaced apart from each other and stacked along a first direction intersecting an upper surface of the substrate, a conductive pillar extending in the first direction and intersecting the plurality of conductive patterns, a semiconductor layer doped with n-type impurities between each of the conductive patterns and the conductive pillar, and a ferroelectric layer between the conductive pillar and the semiconductor layer. In a polarization-voltage hysteresis curve of the ferroelectric layer, a first coercive voltage has a positive value and a second coercive voltage has a value smaller than the first coercive voltage, and an absolute value of the first coercive voltage is greater than an absolute value of the second coercive value.

### CROSS-REFERENCE TO RELATED APPLICATION

This application claims priority from Korean Patent Application No. 10-2025-0020577 filed on February 18, 2025 in the Korean Intellectual Property Office, and all the benefits accruing therefrom under 35 U.S.C. 119, the contents of which in its entirety are herein incorporated by reference.

### BACKGROUND

The present disclosure relates to a semiconductor memory device and a method for fabricating the same. More particularly, the present disclosure relates to a semiconductor memory device including a ferroelectric field-effect transistor (FeFET) and a method for fabricating the same.

Ferroelectrics are materials that exhibit ferroelectricity, in which the internal electric dipole moments are aligned to maintain spontaneous polarization even without an external electric field. Additionally, the polarization of ferroelectric materials may be switched by applying an external electric field exceeding the coercive field, and the state may be electrically read based on changes in materials such as adjacent metals and semiconductors.

### SUMMARY

The present disclosure aims to solve the technical problem of providing a semiconductor memory device with enhanced performance through a simplified process.

Another technical problem that the present disclosure aims to solve is to provide a method for fabricating a semiconductor memory device with enhanced performance through a simplified process.

The technical problems of the present disclosure are not limited to the technical problems mentioned above, and other technical problems not explicitly stated will be clearly understood by those skilled in the art from the following description.

According to an aspect of the present disclosure, there is provided a semiconductor memory device comprising a substrate, a stacked structure on the substrate, wherein the stacked structure includes a plurality of conductive patterns spaced apart from each other and stacked along a first direction that intersects an upper surface of the substrate, a conductive pillar extending in the first direction and intersecting the plurality of conductive patterns;, a semiconductor layer between each conductive pattern of the plurality of conductive patterns and the conductive pillar, wherein the semiconductor layer is doped with n-type impurities, and a ferroelectric layer between the conductive pillar and the semiconductor layer, wherein, the ferroelectric layer is configured to exhibit a polarization-voltage hysteresis curve that has a first coercive voltage having a positive value and a second coercive voltage smaller than the first coercive voltage, and wherein an absolute value of the first coercive voltage is greater than an absolute value of the second coercive voltage.

According to another aspect of the present disclosure, there is provided a semiconductor memory device comprising a substrate, a stacked structure on the substrate, wherein the stacked structure includes a plurality of conductive patterns spaced apart from each other and stacked along a first direction that intersects an upper surface of the substrate, a conductive pillar extending in the first direction and intersecting the plurality of conductive patterns, a semiconductor layer doped between each conductive pattern of the plurality of conductive patterns and the conductive pillar, wherein the semiconductor layer is doped with n-type impurities, a ferroelectric layer between the conductive pillar and the semiconductor layer, wherein the ferroelectric layer comprises a first side surface facing the semiconductor layer and a second side surface facing the conductive pillar, and a fixed charge layer on a side surface of the conductive pillar, wherein the fixed charge layer is configured to apply an electric field to the ferroelectric layer in a direction from the first side surface toward the second side surface.

According to still another aspect of the present disclosure, there is provided a semiconductor memory device comprising a substrate, a stacked structure on the substrate, wherein the stacked structure includes a plurality of conductive patterns spaced apart from each other and stacked along a first direction that intersects an upper surface of the substrate, a conductive pillar extending in the first direction and intersecting the plurality of conductive patterns, a semiconductor layer between each conductive pattern of the plurality of conductive patterns and the conductive pillar, wherein the semiconductor layer is doped with n-type impurities, a ferroelectric layer between the conductive pillar and the semiconductor layer, wherein the ferroelectric layer includes a first side surface facing the semiconductor layer and a second side surface facing the conductive pillar, and a fixed charge layer having a positive charge on the first side surface of the ferroelectric layer, wherein the plurality of conductive patterns include a first conductive pattern and a second conductive pattern spaced apart from each other in the first direction, and wherein the semiconductor layer connects the first conductive pattern and the second conductive pattern and wherein the semiconductor layer does not include a PN junction.

It should be noted that the effects of the present disclosure are not limited to those described above, and other effects of the present disclosure will be apparent from the following description.

### BRIEF DESCRIPTION OF THE DRAWINGS

The above and other aspects and features of the present disclosure will become more apparent by describing in detail illustrative implementations thereof with reference to the attached drawings, in which:

FIG. 1 is an example circuit diagram for explaining a semiconductor memory device according to some implementations.

FIG. 2 is a schematic layout diagram for explaining the semiconductor memory device according to some implementations.

FIG. 3 is a schematic cross-section view taken along line A-A of FIG. 2.

FIG. 4 is an enlarged view for explaining the R region of FIG. 3.

FIG. 5 and FIG. 6 are diagrams for explaining the operation of a semiconductor memory device according to some implementations.

FIG. 7 is a graph showing the polarization-voltage (PV) hysteresis curve of the ferroelectric layer in a semiconductor memory device according to some implementations.

FIGS. 8 and 9 are various enlarged views for explaining the semiconductor memory device according to some implementations.

FIG. 10 is a schematic layout diagram for explaining the semiconductor memory device according to some implementations.

FIG. 11 is a schematic cross-sectional view taken along line B-B of FIG. 10.

FIG. 12 is a schematic layout diagram for explaining the semiconductor memory device according to some implementations.

FIG. 13 is a schematic cross-sectional view taken along line C-C of FIG. 12.

FIG. 14 is a schematic layout diagram for explaining the semiconductor memory device according to some implementations.

FIG. 15 is a schematic cross-sectional view taken along line D-D of FIG. 14.

FIG. 16 is a schematic layout diagram for explaining the semiconductor memory device according to some implementations.

FIG. 17 is a schematic cross-sectional view taken along line E-E of FIG. 16.

FIGS. 18 to 27 are intermediate stage diagrams for explaining a method for fabricating the semiconductor memory device according to some implementations.

### DETAILED DESCRIPTION

It will be understood that, although the terms “first”, “second”, “third”, and so on may be used herein to describe various elements, components, regions, layers and/or sections, these elements, components, regions, layers and/or sections should not be limited by these terms. These terms are used to distinguish one element, component, region, layer or section from another element, component, region, layer or section. Thus, a first element, component, region, layer or section described below could be termed a second element, component, region, layer or section, without departing from the spirit and scope of the present disclosure.

Moreover, as used herein, the term “same” means not only being completely identical but also including a minute difference that may occur due to a margin in a process, etc.

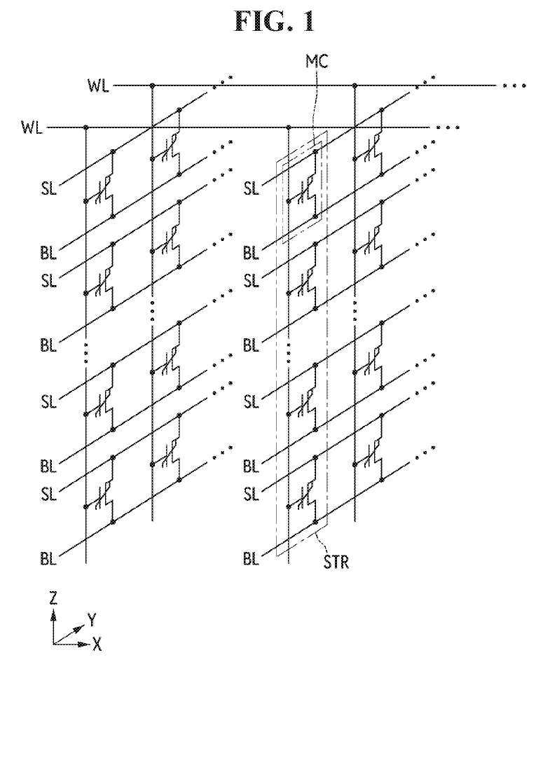

Hereinafter, a semiconductor memory device according to example implementations is described with reference to FIG. 1 to FIG. 17.

FIG. 1 is an example circuit diagram for explaining a semiconductor memory device according to some implementations.

Referring to FIG. 1, the semiconductor memory device according to some implementations may include a plurality of cell strings STR.

The plurality of cell strings STR may each be extended in a first direction Z. The plurality of cell strings STR may be arranged two-dimensionally in a plane intersecting the first direction Z (e.g., an XY plane including a second direction X and a third direction Y). Each of the cell strings STR may include a plurality of memory cells MC arranged along the first direction Z.

Each of the memory cells MC may be connected between word lines WL and bit lines BL that intersect each other. Each of the memory cells MC may be connected between bit lines BL and source lines SL that are parallel to each other. For example, the word line WL may extend in the second direction X to connect commonly to cell strings STR arranged along the second direction X. For example, the bit lines BL and the source lines SL may each extend in the third direction Y to connect commonly to the memory cells MC arranged along the third direction Y.

Each of the memory cells MC may include a ferroelectric field-effect transistor (FeFET). The word line WL may be connected to the gate of the ferroelectric field-effect transistor. The source line SL may be connected to the source of the ferroelectric field-effect transistor. The bit line BL may be connected to the drain of the ferroelectric field-effect transistor. Each of the memory cells MC may store data using the properties of the ferroelectric field-effect transistor. In the following description, the ferroelectric field-effect transistor is exemplified as an n-type field effect transistor (NFET) in which the majority carrier is an electron. However, those skilled in the art will understand that the subject matter of the present disclosure may also be cover ferroelectric field-effect transistors that are p-type field effect transistors (PFET).

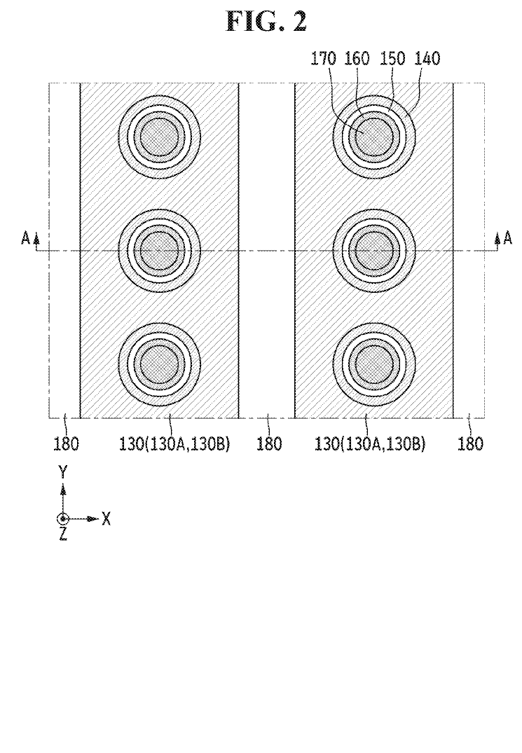

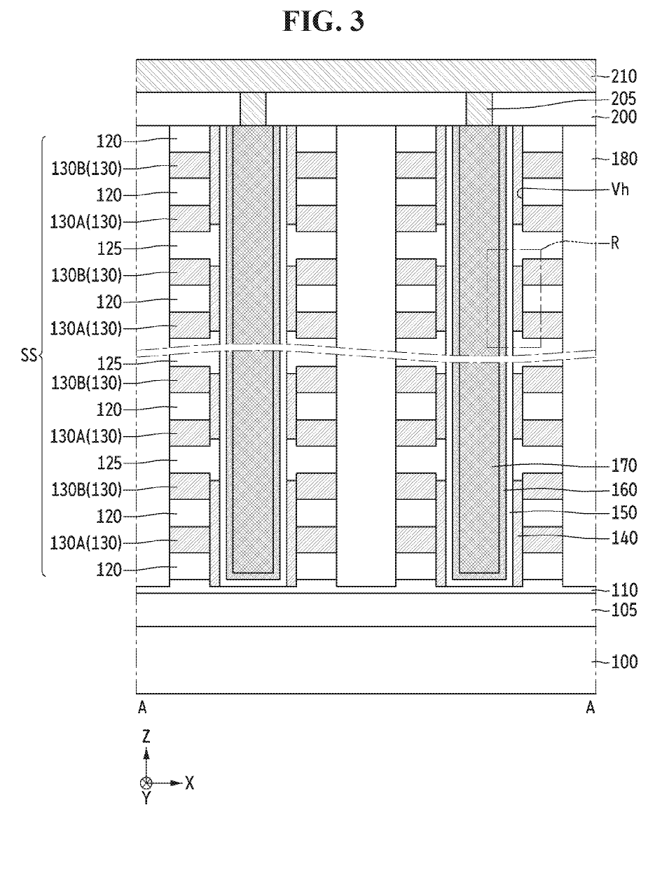

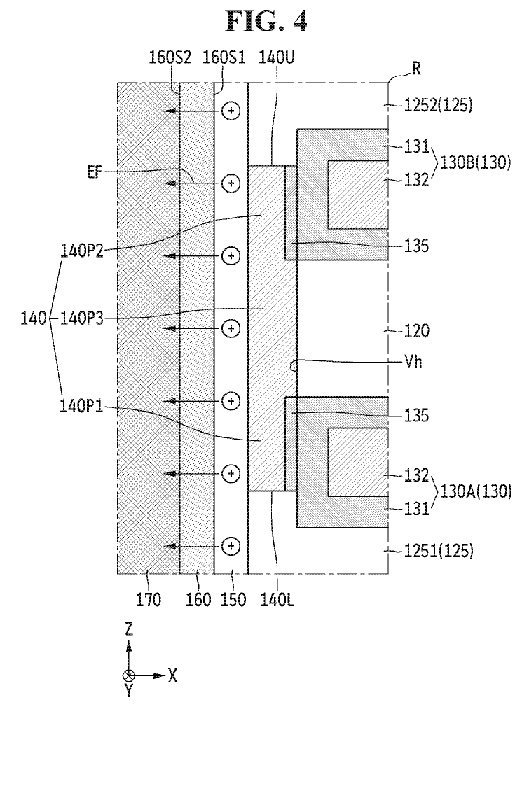

FIG. 2 is a schematic layout diagram for explaining the semiconductor memory device according to some implementations. FIG. 3 is a schematic cross-section view taken along line A-A of FIG. 2. FIG. 4 is an enlarged view for explaining the R region of FIG. 3.

Referring to FIGS. 1 to 4, the semiconductor memory device according to some implementations includes a substrate 100, a lower structure 105, an etch stop layer 110, a stacked structure SS, a semiconductor layer 140, a fixed charge layer 150, a ferroelectric layer 160, a conductive pillar 170, a cutting pattern 180 and a wiring pattern 210.

The substrate 100 may be bulk silicon or silicon-on-insulator (SOI). The substrate 100 may be a silicon substrate or composed of other materials, such as silicon germanium, gallium arsenide, silicon germanium on insulator (SGOI), indium antimonide, lead telluride compounds, indium arsenide, indium phosphide, gallium arsenide, or gallium antimonide. Alternatively, the substrate 100 may be a substrate having an epitaxial layer formed on the base substrate or may be a ceramic substrate, a quartz substrate, or a display glass substrate.

The lower structure 105 may be formed on the substrate 100. The lower structure 105 may include an insulating material, such as at least one of silicon oxide, silicon nitride, silicon oxynitride, silicon oxycarbide, silicon boron nitride, silicon boron carbonitride, silicon oxycarbonitride, or a low-k material with a dielectric constant lower than that of silicon oxide, but is not limited thereto.

In some implementations, the lower structure 105 may include peripheral circuits that are formed on the substrate 100. For example, the lower structure 105 may include the peripheral circuits, multilayer wiring layers electrically connected to the peripheral circuits, and an insulating layer covering the peripheral circuits and the wiring layers. The peripheral circuits may consist of circuits that control the operation of the semiconductor memory device formed on the substrate 100 and the lower structure 105. For example, the peripheral circuits may include various active elements, such as transistors, as well as various passive elements, such as capacitors, resistors, or inductors.

The etch stop layer 110 may be formed on the lower structure 105. For example, the etch stop layer 110 may extend conformally along the upper surface of the lower structure 105. The etch stop layer 110 may have an etch selectivity different from that of the layers forming the stacked structure SS (e.g., the mold insulating layers 120 and conductive patterns 130 described later). For example, the etch stop layer 110 may include an aluminum oxide (AlO) layer but is not limited thereto. The etch stop layer 110 may be provided as an etch stop layer during the etching process for the stacked structure SS.

The stacked structure SS may be formed on the etch stop layer 110. The stacked structure SS may include a plurality of mold insulating layers 120, a plurality of isolation insulating layers 125, and a plurality of conductive patterns 130. The mold insulating layers 120, the isolation insulating layers 125, and the conductive patterns 130 may each be a layer structure extending along the plane (e.g., the XY plane) that intersects the first direction Z.

The plurality of conductive patterns 130 may be spaced apart from each other and stacked in the first direction Z, which intersects the upper surface of the substrate 100. For example, the conductive patterns 130 arranged along the first direction Z may be spaced apart from each other by mold insulating layers 120 and/or the isolation insulating layers 125.

Each conductive pattern 130 may include a conductive material, for example, a metal such as tungsten (W), molybdenum (Mo), ruthenium (Ru), cobalt (Co), or nickel (Ni), or a semiconductor material such as silicon, but is not limited thereto.

The mold insulating layers 120 and the isolation insulating layers 125 may each include at least one of, for example, silicon oxide, silicon nitride, or silicon oxynitride, but are not limited thereto.

In some implementations, as shown in FIG. 4, each of the conductive patterns 130 may include a barrier conductive layer 131 and a filling conductive layer 132. The barrier conductive layer 131 may include a metal or a metal nitride to prevent the diffusion of metal elements contained in the filling conductive layer 132. For example, the barrier conductive layer 131 may include at least one of titanium (Ti), tantalum (Ta), tungsten (W), nickel (Ni), cobalt (Co), platinum (Pt), alloys thereof, or nitrides thereof, but is not limited thereto. The filling conductive layer 132 may fill the remaining region of each conductive pattern 130 after the barrier conductive layer 131 is filled. The filling conductive layer 132 may include at least one of a conductive metal, such as tungsten (W), molybdenum (Mo), or ruthenium (Ru), but is not limited thereto.

The conductive pillar 170 may be formed within the stacked structure SS. The conductive pillar 170 may extend in the first direction Z and intersect with a plurality of conductive patterns 130. For example, a vertical hole Vh extending in the first direction Z may be formed within the stacked structure SS. The vertical hole Vh may extend in the first direction Z and penetrate through the stacked structure SS. The conductive pillar 170 may extend in the first direction Z within the vertical hole Vh. The conductive pillar 170 may serve as the gate of the ferroelectric field-effect transistor of each of the memory cells MC in FIG. 1.

Although the conductive pillar 170 is illustrated as a cylindrical shape extending in the first direction Z, this is only an example. The conductive pillar 170 may also have other various shapes, such as a polygonal pillar or a hollow cylinder.

In the plane intersecting the first direction Z (e.g., the XY plane), a plurality of conductive pillars 170 are shown to be arranged in a lattice form. However, this is only an example. Contrary to what is shown, the plurality of conductive pillars 170 may be arranged in various other forms, such as a honeycomb pattern.

The conductive pillars 170 may include, for example, metals such as tungsten (W), molybdenum (Mo), ruthenium (Ru), cobalt (Co), nickel (Ni), or semiconductor materials such as silicon, but are not limited thereto.

The semiconductor layer 140 may be formed within the stacked structure SS. The semiconductor layer 140 may be interposed between each of the conductive patterns 130 and the conductive pillars 170. For example, the semiconductor layer 140 may extend conformally along at least a portion of the profile of the vertical hole Vh. For example, in the plane intersecting the first direction Z (e.g., the XY plane), the semiconductor layer 140 may have a ring shape that extends conformally along the profile of the outer side of the conductive pillars 170.

Each of the conductive patterns 130 may be connected to the semiconductor layer 140. For example, each of the conductive patterns 130 may be in contact with the outer side surface of the semiconductor layer 140. The semiconductor layer 140 may serve as the channel of the ferroelectric field-effect transistor of each of the memory cells MC in FIG. 1.

In some implementations, the conductive patterns 130 may include a first conductive pattern 130A and a second conductive pattern 130B, which are spaced apart from each other in the first direction Z. For example, the first conductive pattern 130A and the second conductive pattern 130B may be spaced apart from each other in the first direction Z by one of the mold insulating layers 120. The first conductive pattern 130A and the second conductive pattern 130B may each extend longitudinally in the third direction Y. Each of the first conductive pattern 130A and the second conductive pattern 130B may be connected to the semiconductor layer 140. Each of the first conductive pattern 130A and the second conductive pattern 130B may be commonly connected to a plurality of semiconductor layers 140 arranged along the third direction Y. The first conductive pattern 130A may serve as the bit line BL in FIG. 1, and the second conductive pattern 130B may serve as the source line SL in FIG. 1.

In some implementations, as shown in FIG. 4, a silicide layer 135 may be formed between each of the conductive patterns 130 and the semiconductor layer 140. The silicide layer 135 may be formed by a reaction between silicon (Si) included in the semiconductor layer 140 and a metal element. The silicide layer 135 may include, for example, at least one of nickel silicide, cobalt silicide, tungsten silicide, titanium silicide, niobium silicide, tantalum silicide, or a combination thereof, but is not limited thereto.

The semiconductor layer 140 may include an elemental semiconductor material such as silicon (Si) or germanium (Ge). Alternatively, the semiconductor layer 140 may include a compound semiconductor material, such as a group IV-IV compound semiconductor or a group III-V compound semiconductor. The group IV-IV compound semiconductor may be, for example, a binary compound, a ternary compound, or a compound doped with a group IV element, including at least two or more of carbon (C), silicon (Si), germanium (Ge), and tin (Sn). The group III-V compound semiconductor may be one of a binary compound, a ternary compound, or a quaternary compound formed by combining at least one of the group III elements, such as aluminum (Al), gallium (Ga), and indium (In) with at least one of the group V elements, such as phosphorus (P), arsenic (As), and antimony (Sb).

Alternatively, the semiconductor layer 140 may include a two-dimensional semiconductor material or an oxide semiconductor material. Such a semiconductor layer 140 may enhance the performance of the semiconductor memory device by improving mobility and mitigating short channel effects (SCE).

The two-dimensional semiconductor material may include, for example, graphene, carbon nanotubes, a two-dimensional chalcogenide containing a chalcogen element, or combinations thereof, but is not limited thereto. The chalcogen element belongs to group 16 of the periodic table and may include at least one of oxygen (O), sulfur (S), selenium (Se), tellurium (Te), polonium (Po), and livermorium (Lv).

For example, the two-dimensional chalcogenide may include a two-dimensional chalcogenide in which a semiconductor element and a chalcogen element are combined. For example, the two-dimensional chalcogenide may include at least one of silicon sulfide (Si₂S₃), silicon selenide (Si₂Se₃), silicon telluride (Si₂Te₃), germanium sulfide (Ge₂S₃), germanium selenide (Ge₂Se₃), germanium telluride (Ge₂Te₃), or combinations thereof.

As another example, the two-dimensional chalcogenide may include a transition metal dichalcogenide (TMD). The transition metal dichalcogenide (TMD) may include, for example, a transition metal element selected from Mo, W, Nb, V, Ta, Ti, Zr, Hf, Tc, Re, Cu, Ga, In, Sn, Ge, and Pb, and a chalcogen element selected from S, Se, and Te.

The oxide semiconductor material may include, for example, at least one of zinc oxide (ZnO), tin oxide (SnO), copper oxide (CuO), or nickel oxide (NiO) but is not limited thereto.

In some implementations, the semiconductor layer 140 may be a junctionless semiconductor material layer that does not include a PN junction. For example, the semiconductor layer 140 may be a polysilicon layer (poly-Si) doped with n-type impurities (e.g., phosphorus (P), antimony (Sb), or arsenic (As)).

In some implementations, the semiconductor layer 140 may connect the first conductive pattern 130A and the second conductive pattern 130B. For example, as shown in FIG. 4, the semiconductor layer 140 may include a first portion 140P1, a second portion 140P2, and a third portion 140P3. The first portion 140P1 may overlap with at least a portion of the first conductive pattern 130A in the horizontal direction (e.g., the second direction X or the third direction Y). The outer side surface of the first portion 140P1 may be connected to the first conductive pattern 130A. The second portion 140P2 may overlap with at least a portion of the second conductive pattern 130B in the horizontal direction (e.g., the second direction X or the third direction Y). The outer side surface of the second portion 140P2 may be connected to the second conductive pattern 130B. The third portion 140P3 may be interposed between the first portion 140P1 and the second portion 140P2. The third portion 140P3 may extend in the first direction Z to connect the first portion 140P1 and the second portion 140P2. The first portion 140P1, the second portion 140P2, and the third portion 140P3 may be connected to form an integral junctionless semiconductor material layer (e.g., an n-type semiconductor material layer).

In some implementations, each of the isolation insulating layers 125 may cut the semiconductor layer 140. As shown in FIG. 3, the semiconductor layer 140 cut by the isolation insulating layers 125 may form a plurality of semiconductor patterns spaced apart from each other in the first direction Z. For example, as shown in FIG. 4, the plurality of isolation insulating layers 125 may include a first isolation insulating layer 1251 and a second isolation insulating layer 1252, which are spaced apart from each other in the first direction Z. The first conductive pattern 130A and the second conductive pattern 130B may be interposed between the first isolation insulating layer 1251 and the second isolation insulating layer 1252. The first isolation insulating layer 1251 may be disposed at the lower surface of the first conductive pattern 130A and may cut the semiconductor layer 140. A portion of the first isolation insulating layer 1251 may be in contact with the lower surface 140L of the semiconductor layer 140. The second isolation insulating layer 1252 may be disposed on the upper surface of the second conductive pattern 130B and may cut the semiconductor layer 140. A portion of the second isolation insulating layer 1252 may be in contact with the upper surface 140U of the semiconductor layer 140.

In some implementations, a portion of the first isolation insulating layer 1251 may be interposed between the conductive pillar 170 and the first conductive pattern 130A in the horizontal direction (e.g., the second direction X or the third direction Y). For example, the lower surface 140L of the semiconductor layer 140 may be recessed to be positioned higher than the lower surface of the first conductive pattern 130A.

In some implementations, a portion of the second insulating layer 1252 may be interposed between the conductive pillar 170 and the second conductive pattern 130B in the horizontal direction (e.g., the second direction X or the third direction Y). For example, the upper surface 140U of the semiconductor layer 140 may be recessed to be positioned lower than the upper surface of the second conductive pattern 130B.

The ferroelectric layer 160 may be formed within the vertical hole Vh. The ferroelectric layer 160 may be interposed between the semiconductor layer 140 and the conductive pillar 170. For example, in the plane intersecting the first direction Z (e.g., the XY plane), the ferroelectric layer 160 may have a ring shape that conformally extends along the profile of the outer side surface of the conductive pillar 170 and/or the profile of the inner side surface of the semiconductor layer 140.

The ferroelectric layer 160 may exhibit ferroelectricity. Ferroelectricity refers to the property of spontaneous polarization, where the polarization direction may be switched by an external electric field. For example, the ferroelectric layer 160 may include at least one of hafnium oxide, hafnium nitride, zirconium oxide, yttrium-doped zirconium oxide, yttrium-doped hafnium oxide, magnesium-doped zirconium oxide, magnesium-doped hafnium oxide, silicon-doped hafnium oxide, silicon-doped zirconium oxide, barium-doped titanium oxide, or combinations thereof. For example, the ferroelectric layer 160 may include hafnium oxide.

The fixed charge layer 150 may be formed within the vertical hole Vh. The fixed charge layer 150 may be configured to apply a predetermined electric field to the ferroelectric layer 160. For example, as shown in FIG. 4, the ferroelectric layer 160 may include a first side surface 160S1 facing the semiconductor layer 140 and a second side surface 160S2 facing the conductive pillar 170. When the ferroelectric field-effect transistor including the ferroelectric layer 160 is an NFET, the fixed charge layer 150 may apply an electric field to the ferroelectric layer 160 in the direction from the first side surface 160S1 toward the second side surface 160S2.

In some implementations, the fixed charge layer 150 may be disposed on the first side surface 160S1 of the ferroelectric layer 160 and may have a positive charge. Accordingly, the fixed charge layer 150 may apply an electric field to the ferroelectric layer 160 in the direction from the first side surface 160S1 toward the second side surface 160S2.

In some implementations, the fixed charge layer 150 may be interposed between the semiconductor layer 140 and the ferroelectric layer 160. For example, in the plane intersecting the first direction Z (e.g., the XY plane), the fixed charge layer 150 may have a ring shape that conformally extends along the profile of the outer side surface of the ferroelectric layer 160 and/or the profile of the inner side surface of the semiconductor layer 140.

The fixed charge layer 150 with a positive charge may include, for example, at least one of silicon oxide (SiO₂), silicon nitride (SiN), aluminum oxide (Al₂O₃), tantalum oxide (Ta₂O₅), niobium oxide (Nb₂O₅), hafnium oxide (HfO₂), zirconium oxide (ZrO₂), titanium oxide (TiO₂), vanadium oxide (V₂O₅), or combinations thereof, but is not limited thereto.

The cutting pattern 180 may be formed on the etch stop layer 110. The cutting pattern 180 may extend longitudinally in the third direction Y to cut the stacked structure SS. A plurality of cutting patterns 180 may be spaced apart from each other in the second direction X and arranged accordingly. The stacked structure SS may be divided by the plurality of cutting patterns 180 to form a plurality of memory cell blocks.

The cutting pattern 180 may include at least one of insulating materials, such as silicon oxide, silicon nitride, and/or silicon oxynitride, but is not limited thereto. For example, the cutting pattern 180 may include a silicon oxide layer.

The wiring pattern 210 may be formed on the stacked structure SS. For example, an upper insulating layer 200 covering the upper surface of the stacked structure SS may be formed. The wiring pattern 210 may extend along the upper surface of the upper insulating layer 200. The wiring pattern 210 may extend longitudinally in the second direction X. A plurality of wiring patterns 210 may be spaced apart from each other in the third direction Y and arranged accordingly.

The wiring pattern 210 may be connected to the conductive pillar 170. For example, a contact 205 may be formed through the upper insulating layer 200 to connect the conductive pillar 170 and the wiring pattern 210. The wiring pattern 210 may be commonly connected to a plurality of conductive pillars 170 arranged along the second direction X. The wiring pattern 210 may be provided as the word line WL shown in FIG. 1.

The wiring pattern 210 is depicted as being disposed only on the upper surface of the stacked structure SS, but this is only an example. In some implementations the wiring pattern 210 may be disposed on the lower surface of the stacked structure SS (e.g., between the lower structure 105 and the stacked structure SS).

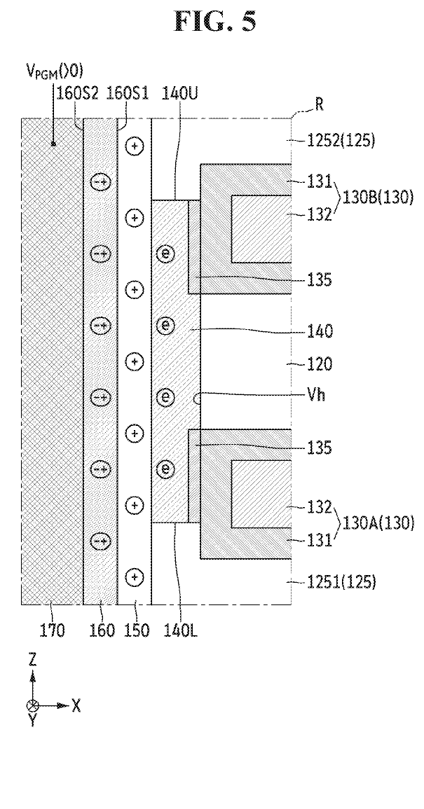

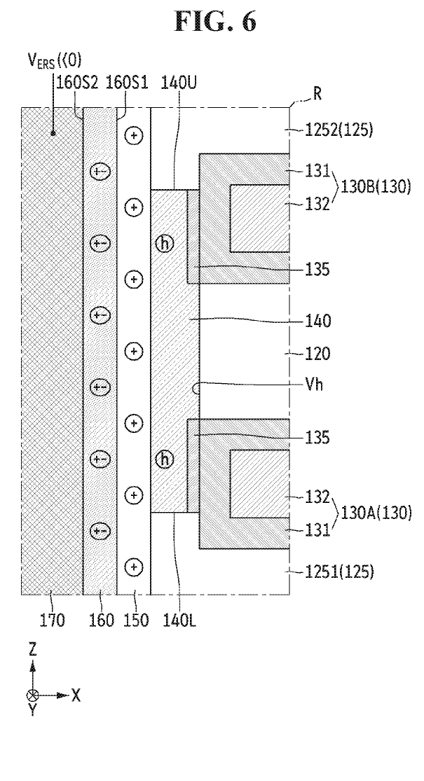

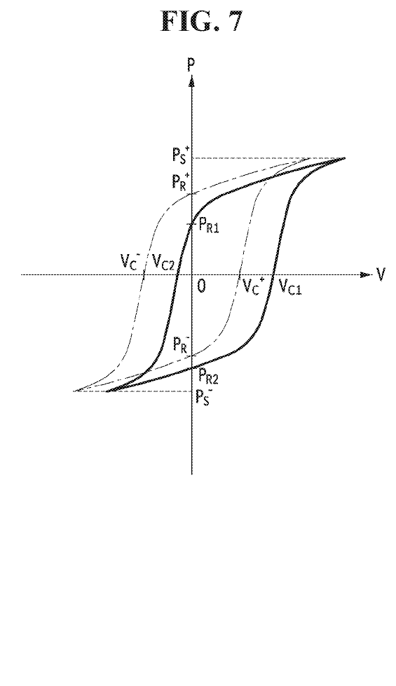

FIG. 5 and FIG. 6 are diagrams for explaining the operation of a semiconductor memory device according to some implementations. FIG. 7 is a graph showing the polarization- voltage (PV) hysteresis curve of the ferroelectric layer in a semiconductor memory device according to some implementations. For convenience of explanation, redundant details that overlap with those described above using FIGS. 1 to 4 are briefly explained or omitted.

Referring to FIG. 5, a programming operation of the semiconductor memory device according to some implementations is performed.

During the programming operation, a programming voltage (V_{PGM}) with a positive (+) value may be applied to the conductive pillar 170. As the programming operation is performed, the dipoles of the ferroelectric layer 160 may be oriented such that their negative poles face the conductive pillar 170 and their positive poles face the semiconductor layer 140. Accordingly, the ferroelectric field-effect transistor including the semiconductor layer 140 may have a relatively low threshold voltage.

Referring to FIG. 6, an erase operation of the semiconductor memory device according to some implementations is performed.

During the erase operation, an erase voltage (V_{ERS}) having a negative (-) value may be applied to the conductive pillar 170. As the erase operation is performed, the dipoles of the ferroelectric layer 160 may be oriented such that their positive poles face the conductive pillar 170 and their negative poles face the semiconductor layer 140. Accordingly, the ferroelectric field-effect transistor including the semiconductor layer 140 may have a relatively high threshold voltage.

Referring to FIGS. 5 to 7, in a semiconductor memory device according to some implementations, the polarization-voltage PV hysteresis curve of the ferroelectric layer 160 is shifted due to the fixed charge layer 150.

In the PV hysteresis curve in FIG. 7, a positive saturation polarization P_{S}⁺ and a negative saturation polarization P_{S}⁻ may be defined. The positive saturation polarization P_{S}⁺, for example, may be defined as the maximum polarization value that the ferroelectric layer 160 may have by the programming operation according to FIG. 5. The negative saturation polarization P_{S}⁻, for example, may be defined as the minimum polarization value that the ferroelectric layer 160 may have by the erase operation according to FIG. 6. In some implementations, the absolute values of the positive saturation polarization P_{S}⁺ and the negative saturation polarization P_{S}⁻ may be the same.

In FIG. 7, the dashed line represents the PV hysteresis curve of the ferroelectric layer 160 in the ferroelectric field-effect transistor in which the fixed charge layer 150 is omitted.

When the fixed charge layer 150 is omitted, a positive coercive voltage V_{C}⁺ and a negative coercive voltage V_{C}⁻ may be defined in the PV hysteresis curve of the ferroelectric layer 160. The positive coercive voltage V_{C}⁺ may be defined as, for example, the voltage value that reverses the orientation of the dipoles of the ferroelectric layer 160 (or brings the polarization value to zero) during the programming operation process according to FIG. 5. The negative coercive voltage V_{C}⁻ may be defined as, for example, the voltage value that reverses the orientation of the dipoles of the ferroelectric layer 160 (or brings the polarization value to zero) during the erase operation according to FIG. 6. In some implementations, the absolute values of the positive coercive voltage V_{C}⁺ and the negative coercive voltage V_{C}⁻ may be the same.

When the fixed charge layer 150 is omitted, a positive remanent polarization P_{R}⁺ and a negative remanent polarization P_{R}⁻ may be defined in the PV hysteresis curve of the ferroelectric layer 160. The positive remanent polarization P_{R}⁺, for example, may be defined as the polarization value when no electric field is applied to the ferroelectric layer 160 (or when the voltage value is zero) after the programming operation according to FIG. 5. The negative remanent polarization P_{R}⁻, for example, may be defined as the polarization value when no electric field is applied to the ferroelectric layer 160 (or when the voltage value is zero) after the erase operation according to FIG. 6. In some implementations, the absolute value of the positive remanent polarization P_{R}⁺ and the absolute value of the negative remanent polarization P_{R}⁻ may be the same.

In FIG. 7, the solid line represents the PV hysteresis curve of the ferroelectric layer 160 in the ferroelectric field-effect transistor that includes the fixed charge layer 150. As the fixed charge layer 150 is interposed, the PV hysteresis curve of the ferroelectric layer 160 may have a shape that is shifted in the positive voltage direction (i.e. to the right).

For example, as described with reference to FIGS. 1 to 4, the fixed charge layer 150 may apply an electric field to the ferroelectric layer 160 in the direction from the first side surface 160S1 toward the second side surface 160S2. Accordingly, in the programming operation process according to FIG. 5, the first coercive voltage V_{C1}for reversing the orientation of the dipoles in the ferroelectric layer 160 may have a greater value than the positive coercive voltage V_{C}⁺. Additionally, in the process of the erase operation according to FIG. 6, the second coercive voltage V_{C2}for reversing the orientation of the dipoles of the ferroelectric layer 160 may have a greater value than the negative coercive voltage V_{C}^{-.}

For the same reason, the first remanent polarization P_{R1}, which is the polarization value of the ferroelectric layer 160 after the programming operation according to FIG. 5, may be smaller than positive remanent polarization P_{R}⁺. Additionally, the second remanent polarization P_{R2}, which is the polarization value of the ferroelectric layer 160 after the erase operation according to FIG. 6, may be smaller the negative remanent polarization P_{R}⁻.

As the PV hysteresis curve of the ferroelectric layer 160 shifts, the absolute values of the first coercive voltage V_{C1} and the second coercive voltage V_{C2} may be different from each other. For example, as the PV hysteresis curve of the ferroelectric layer 160 shifts in the positive voltage direction (i.e. to the right), the absolute value of the first coercive voltage V_{C1} may be greater than the absolute value of the second coercive voltage V_{C2}. The absolute value of the first coercive voltage V_{C1} may be, for example, at least about 1.5 times, at least about 2 times, or at least about 5 times the absolute value of the second coercive voltage V_{C2}. The absolute value of the first coercive voltage V_{C1} may be, for example, at most about 10 times, at most about 100 times, or at most about 1000 times the absolute value of the second coercive voltage V_{C2}.

For the same reason, the absolute values of the first remanent polarization P_{R1} and the second remanent polarization P_{R2} may be different from each other. For example, as the PV hysteresis curve of the ferroelectric layer 160 shifts in the positive voltage direction (i.e., to the right), the absolute value of the first remanent polarization P_{R1} may be smaller than the absolute value of the second remanent polarization P_{R2}.

As semiconductor memory devices capable of storing large amounts of data are required in electronic systems, methods to increase the data storage capacity of semiconductor memory devices are being actively studied. As one of the methods to increase the data storage capacity of semiconductor memory devices, a semiconductor memory device containing three-dimensionally arranged memory cells instead of two-dimensionally arranged memory cells is being proposed. Particularly, in the semiconductor memory device in which memory cells using ferroelectric materials are arranged in three dimensions, a junctionless semiconductor material layer that does not include a PN junction is being studied to reduce the process complexity. However, the junctionless semiconductor material layer tends to exhibit reduced operational efficiency, which leads to a decreased memory window. For example, when an n-type semiconductor material layer is used as a channel, the efficiency of the erase operation may be reduced due to a lack of supply of minority carriers, such as holes.

In the semiconductor memory device of some implementations, an improved memory window may be provided even when the junctionless semiconductor material layer is used as a channel by shifting the PV hysteresis curve of the ferroelectric layer 160 using the fixed charge layer 150. For example, as shown in FIG. 6, during the erase operation, the fixed charge layer 150 with positive charges may compensate for holes, the minority carriers, of which there are otherwise insufficiently many, to enhance the efficiency of the erase operation. Additionally, as shown in FIG. 5, during a programming operation, even if the fixed charge layer 150 is present, the efficiency of the programming operation may not be degraded due to the electrons, which are majority carriers. Through this approach, a semiconductor memory device with improved performance may be provided through a simplified process.

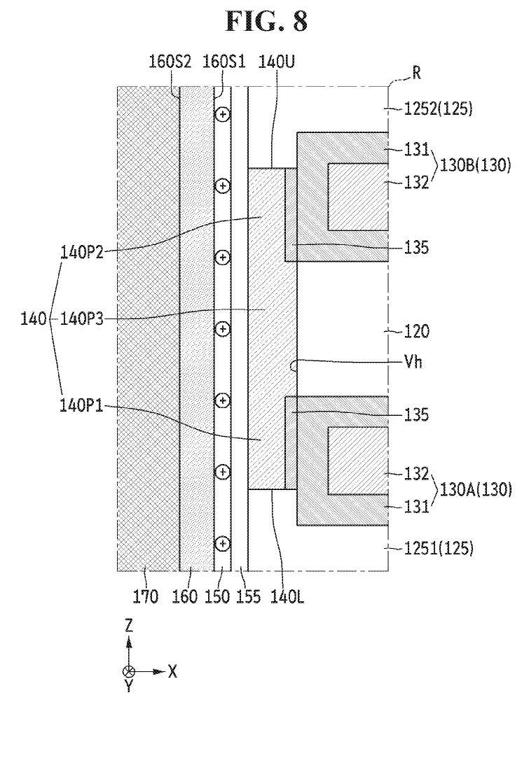

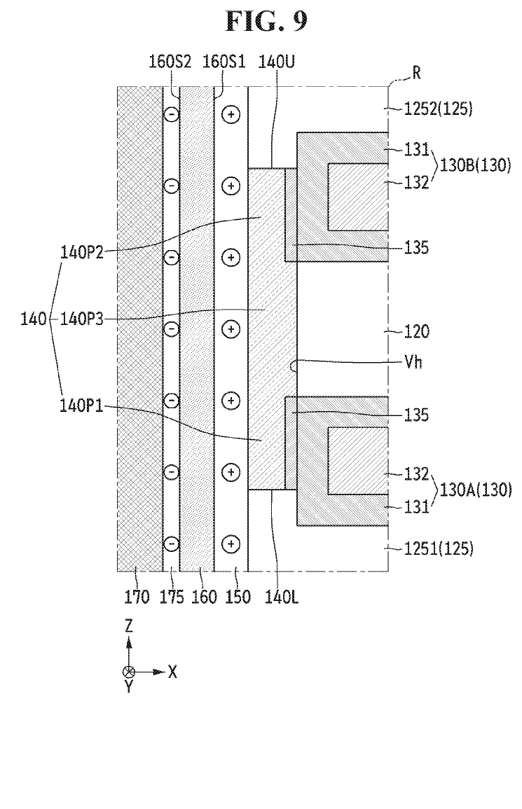

FIGS. 8 and 9 are various enlarged views for explaining the semiconductor memory device according to some implementations. For the sake of convenience of explanation, the parts that are redundant with the above description using FIGS. 1 to 7 are briefly described or omitted.

Referring to FIG. 8, the semiconductor memory device according to some implementations further includes an electric field induction layer 155.

The electric field induction layer 155 may be configured to form the fixed charge layer 150 with positive charges on the first side surface 160S1 of the ferroelectric layer 160. For example, the electric field induction layer 155 may be interposed between the semiconductor layer 140 and the ferroelectric layer 160. The electric field induction layer 155 may induce the formation of positive charges in a portion of the adjacent ferroelectric layer 160. Through this, the fixed charge layer 150 with positive charges may be formed between the ferroelectric layer 160 and the electric field induction layer 155.

In some implementations, the electron affinity of the electric field induction layer 155 may be greater than the electron affinity of the ferroelectric layer 160. In this case, a portion of the ferroelectric layer 160 may lose electrons due to the electric field induction layer 155, thereby forming the fixed charge layer 150 with positive charges. For example, the electric field induction layer 155 may include at least one of titanium oxide (TiO₂), titanium oxynitride (TiON), or a combination thereof.

In some implementations, the oxygen affinity of the electric field induction layer 155 may be greater than the oxygen affinity of the ferroelectric layer 160. For example, the oxide bonding energy of the material constituting the electric field induction layer 155 may be greater than the oxide bonding energy of the material constituting the ferroelectric layer 160. Alternatively, the oxide free energy of the material constituting the electric field induction layer 155 may be less than the oxide free energy of the material constituting the ferroelectric layer 160. In such cases, the electric field induction layer 155 may form the fixed charge layer 150 with positive charges by creating oxygen vacancies within a portion of the ferroelectric layer 160. For example, the electric field induction layer 155 may include at least one of titanium oxide (TiO₂), aluminum oxide (Al₂O₃), lanthanum oxide (La₂O₃), gadolinium oxide (Gd₂O₅), niobium oxide (Nb₂O₅), or a combination thereof. In another example, the electric field induction layer 155 may include a metal-rich oxide, in which the ratio of metal atoms to oxygen atoms is high. The metal-rich oxide may include, for example, at least one of hafnium (Hf), aluminum (Al), titanium (Ti), zirconium (Zr), gallium (Ga), or a combination thereof, but is not limited thereto.

Referring to FIG. 9, the semiconductor memory device according to some implementations further includes a gate dielectric layer 175.

The gate dielectric layer 175 may be formed within the vertical hole Vh. The gate dielectric layer 175 may be interposed between the conductive pillar 170 and the ferroelectric layer 160. For example, in the plane intersecting the first direction Z (e.g., an XY plane), the gate dielectric layer 175 may have a ring shape that conformally extends along the profile of the outer side surface of the conductive pillar 170 and/or the profile of the inner side surface of the ferroelectric layer 160.

The gate dielectric layer 175 may include a dielectric material, for example, at least one of silicon oxide, silicon nitride, silicon oxynitride, and a high-k dielectric material having a dielectric constant greater than that of silicon oxide but is not limited thereto. Alternatively, for example, the gate dielectric layer 175 may include at least one of a hafnium-based oxide, a hafnium-based nitride, a hafnium-based carbide, a zirconium-based oxide, a zirconium-based nitride, a zirconium-based carbide, or a combination thereof. For example, the gate dielectric layer 175 may include at least one of hafnium oxide (HfO), hafnium nitride (HfN), hafnium oxynitride (HfON), hafnium carbonitride (HfCN), hafnium oxycarbonitride (HfOCN), zirconium oxide (ZrO), zirconium nitride (ZrN), zirconium oxynitride (ZrON), zirconium carbonitride (ZrCN), zirconium oxycarbonitride (ZrOCN), or a combination thereof.

In some implementations, the gate dielectric layer 175 may be positioned on the second side surface 160S2 of the ferroelectric layer 160 and may have a negative charge. Accordingly, the gate dielectric layer 175 may apply an electric field to the ferroelectric layer 160 in the direction from the first side surface 160S1 toward the second side 160S2.

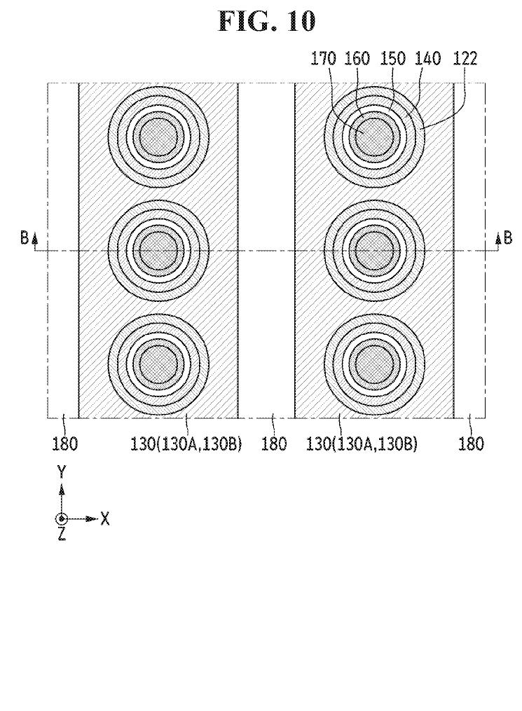

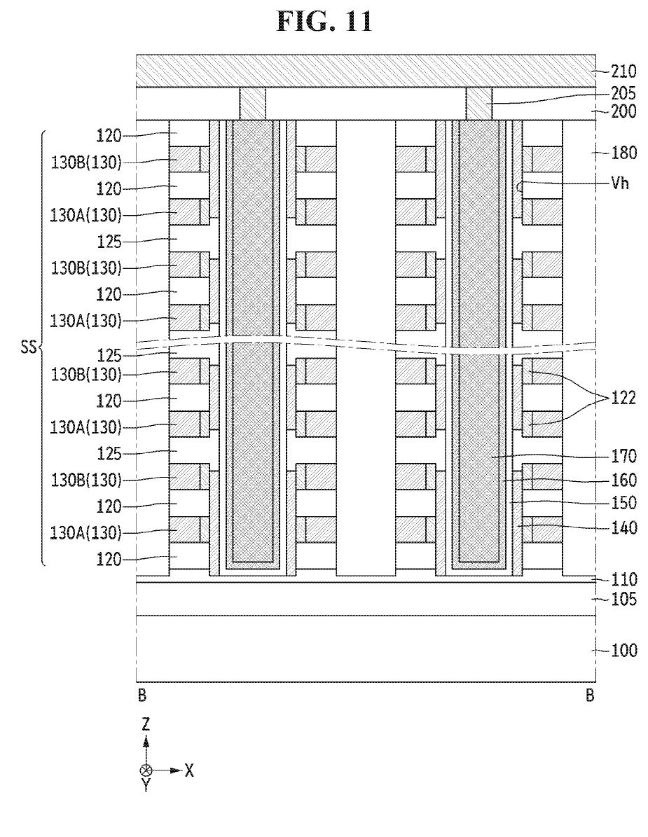

FIG. 10 is a schematic layout diagram for explaining the semiconductor memory device according to some implementations. FIG. 11 is a schematic cross-sectional view taken along line B-B of FIG. 10. For the sake of convenience, redundant descriptions of elements already detailed using FIGS. 1 to 9 will be briefly explained or omitted.

Referring to FIGS. 10 and 11, the semiconductor memory device according to some implementations further includes a plurality of mold sacrificial layers 122.

The plurality of mold sacrificial layers 122 can be spaced apart from each other and stacked in the first direction Z. For example, the mold sacrificial layers 122 arranged along the first direction Z may be spaced apart from each other by the mold insulating layers 120 and/or the isolation insulating layers 125. Each mold sacrificial layer 122 may be interposed between the conductive patterns 130 and the semiconductor layer 140. For example, one of the mold sacrificial layers 122 may be interposed between the first conductive pattern 130A and the semiconductor layer 140, and another one of the mold sacrificial layers 122 may be interposed between the second conductive pattern 130B and the semiconductor layer 140.

Each mold sacrificial layer 122 may connect the conductive patterns 130 to the semiconductor layer 140. For example, in the plane intersecting the first direction Z (e.g., the XY plane), each of the mold sacrificial layers 122 may have a ring shape that conformally extends along the profile of the outer side surface of the semiconductor layer 140.

In some implementations, each of the mold sacrificial layers 122 may be a polysilicon layer (poly-Si) doped with an n-type impurity (e.g., phosphorus (P), antimony (Sb), or arsenic (As), etc.).

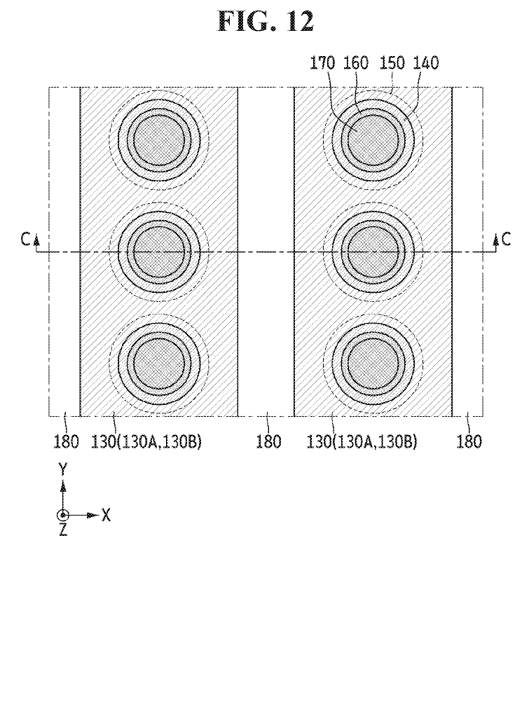

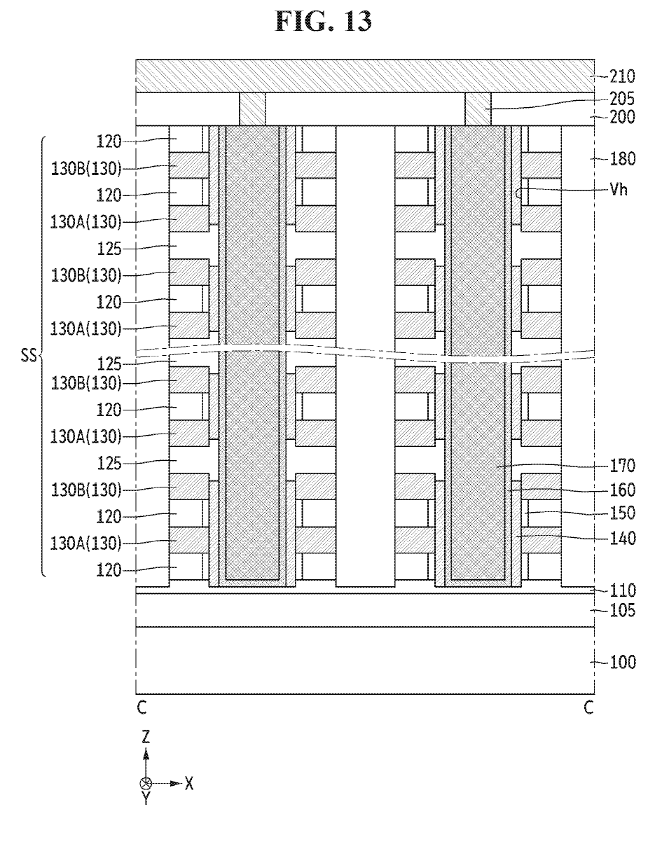

FIG. 12 is a schematic layout diagram for explaining the semiconductor memory device according to some implementations. FIG. 13 is a schematic cross-sectional view taken along line C-C of FIG. 12. For the sake of convenience, redundant descriptions of overlapping parts with those previously described using FIGS. 1 to 11 are either briefly explained or omitted.

Referring to FIGS. 12 and 13, in the semiconductor memory device according to some implementations, the semiconductor layer 140 is interposed between the ferroelectric layer 160 and the fixed charge layer 150.

For example, in the plane intersecting the first direction Z (e.g., an XY plane), the fixed charge layer 150 may have a ring shape that conformally extends along the profile of the outer side surface of the semiconductor layer 140. In some implementations, the fixed charge layer 150 may be interposed between the first conductive pattern 130A and the second conductive pattern 130B in the first direction Z.

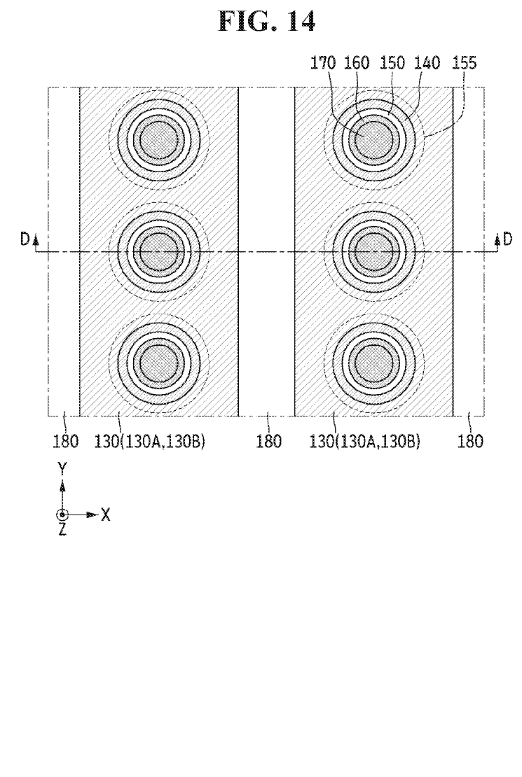

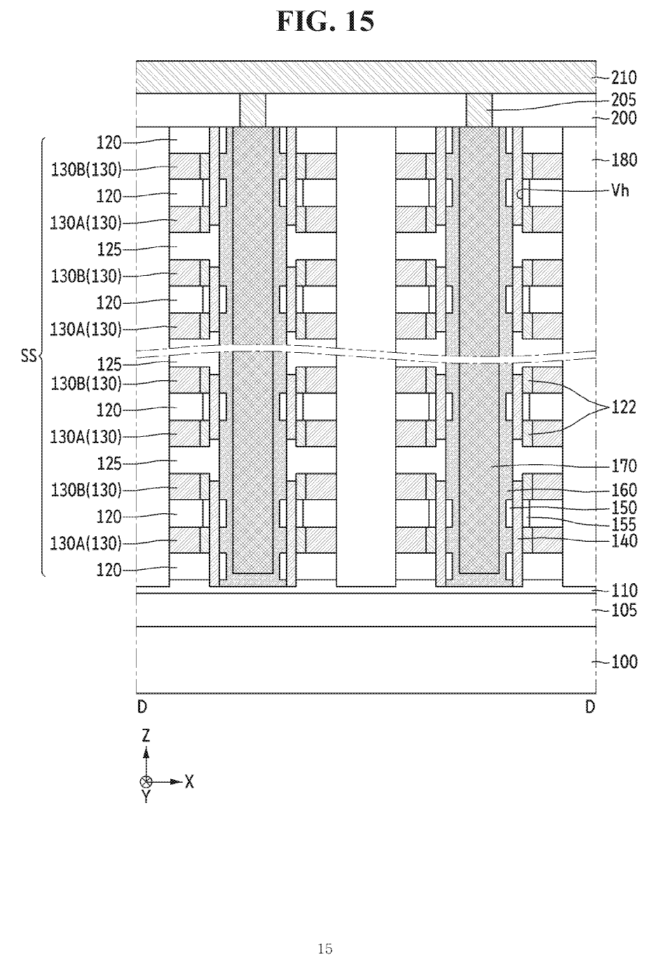

FIG. 14 is a schematic layout diagram for explaining the semiconductor memory device according to some implementations. FIG. 15 is a schematic cross-sectional view taken along line D-D of FIG. 14. For the sake of convenience, redundant descriptions of overlapping parts with those previously described using FIGS. 1 to 11 are either briefly explained or omitted.

Referring to FIGS. 14 and 15, in the semiconductor memory device according to some implementations, the semiconductor layer 140 is interposed between the ferroelectric layer 160 and the field induction layer 155.

For example, in the plane intersecting the first direction Z (e.g., the XY plane), the field induction layer 155 may have a ring shape that conformally extends along the profile of the outer side surface of the semiconductor layer 140. In some implementations, the field induction layer 155 may be interposed between the first conductive pattern 130A and the second conductive pattern 130B in the first direction Z.

The field induction layer 155 may be configured to form the fixed charge layer 150. For example, the field induction layer 155 may induce the formation of the fixed charge layer 150 having positive charges between the semiconductor layer 140 and the ferroelectric layer 160.

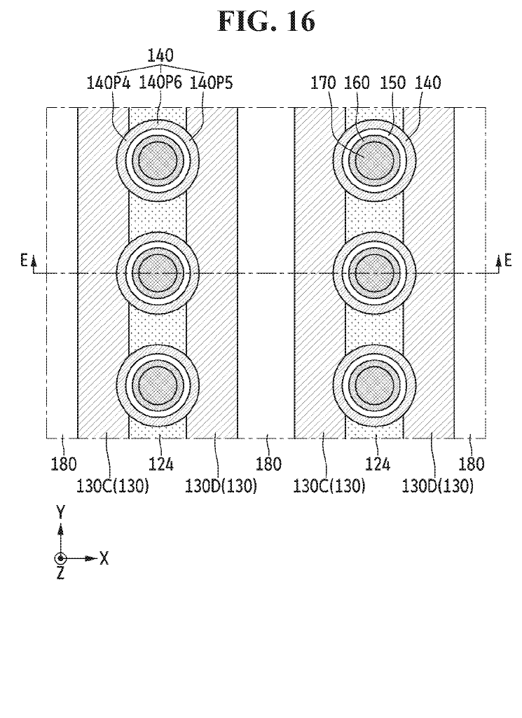

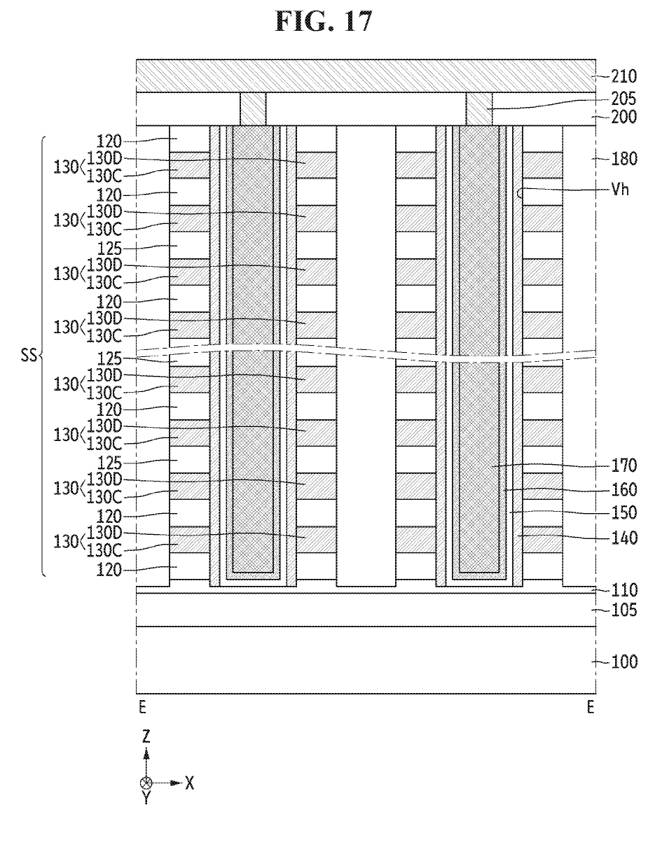

FIG. 16 is a schematic layout diagram for explaining the semiconductor memory device according to some implementations. FIG. 17 is a schematic cross-sectional view taken along line E-E of FIG. 16. For the sake of convenience, parts that are redundant with the above description using FIG. 1 to FIG. 15 are briefly explained or omitted.

Referring to FIGS. 16 and 17, in the semiconductor memory device according to some implementations, the conductive patterns 130 include a third conductive pattern 130C and a fourth conductive pattern 130D, which are spaced apart from each other in the second direction X.

For example, the stacked structure SS may include a plurality of sacrificial insulating layers 124. The mold insulating layers 120 and the sacrificial insulating layers 124 may be alternately stacked along the first direction Z. The mold insulating layers 120 and the sacrificial insulating layers 124 may each be a layer structure extending along the plane intersecting the first direction Z (e.g., an XY plane). The third conductive pattern 130C may be alternately stacked with the mold insulating layers 120 along the first direction Z. The third conductive pattern 130C and the fourth conductive pattern 130D may each be positioned at the same level as one of the sacrificial insulating layers 124. The third conductive pattern 130C and the fourth conductive pattern 130D may be spaced apart from each other in the second direction X by one of the sacrificial insulating layers 124. The third conductive pattern 130C and the fourth conductive pattern 130D may each extend longitudinally in the third direction Y. The third conductive pattern 130C and the fourth conductive pattern 130D may each be connected to the semiconductor layer 140. The third conductive pattern 130C and the fourth conductive pattern 130D may each be commonly connected to a plurality of semiconductor layers 140 arranged along the third direction Y. The third conductive pattern 130C may serve as the bit line BL in FIG. 1, while the fourth conductive pattern 130D may serve as the source line SL in FIG. 1.

The sacrificial insulating layers 124 may each contain, for example, at least one of silicon oxide, silicon nitride, or silicon oxynitride, but are not limited thereto.

In some implementations, the semiconductor layer 140 may connect the third conductive pattern 130C and the fourth conductive pattern 130D. For example, as shown in FIG. 16, the semiconductor layer 140 may include a fourth portion 140P4, a fifth portion 140P5, and a sixth portion 140P6. The outer side surface of the fourth portion 140P4 may be connected to the third conductive pattern 130C. The outer side surface of the fifth portion 140P5 may be connected to the fourth conductive pattern 130D. The sixth portion 140P6 may be interposed between the fourth portion 140P4 and the fifth portion 140P5. The sixth portion 140P6 may extend in the second direction X to connect the fourth portion 140P4 and the fifth portion 140P5. The fourth portion 140P4, the fifth portion 140P5, and the sixth portion 140P6 may be interconnected to form an integrated junctionless semiconductor material layer (e.g., an n-type semiconductor material layer).

Hereinafter, a method for fabricating the semiconductor memory device according to some implementations will be described with reference to FIGS. 1 to 27.

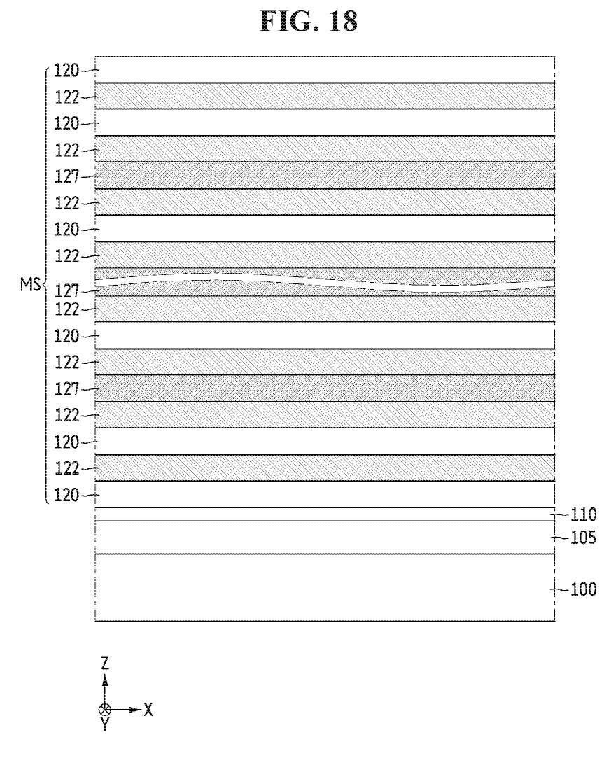

FIGS. 18 to 27 are intermediate stage diagrams for explaining a method for fabricating the semiconductor memory device according to some implementations. For the sake of convenience, redundant descriptions of overlapping parts with those previously described using FIGS. 1 to 17 are either briefly explained or omitted.

Referring to FIG. 18, the lower structure 105, the etch stop layer 110, and the mold structure MS are formed on the substrate 100.

The mold structure MS may be formed on the etch stop layer 110. The mold structure MS may include a plurality of mold insulating layers 120, a plurality of mold sacrificial layers 122, and a plurality of isolation sacrificial layers 127. The mold insulating layers 120, the mold sacrificial layers 122, and the isolation sacrificial layers 127 may each have a layer structure extending along the plane intersecting the first direction Z (e.g., the XY plane).

The plurality of mold sacrificial layers 122 may be spaced apart from each other and stacked in the first direction Z. For example, the mold sacrificial layers 122 arranged along the first direction Z may be spaced apart from each other by the mold insulating layers 120 and/or the isolation sacrificial layers 127.

The isolation sacrificial layers 127 may have an etch selectivity with respect to the mold insulating layers 120 and the mold sacrificial layers 122. The mold sacrificial layers 122 may have an etch selectivity relative to the mold insulating layers 120. For example, each mold insulating layer 120 may include a silicon oxide layer, each mold sacrificial layer 122 may include a polysilicon layer, and each isolation sacrificial layer 127 may include a silicon nitride layer.

In some implementations, the mold sacrificial layers 122 may be conductive materials, such as polysilicon layers (poly-Si) doped with n-type impurities (e.g., phosphorus (P), antimony (Sb), or arsenic (As), etc.).

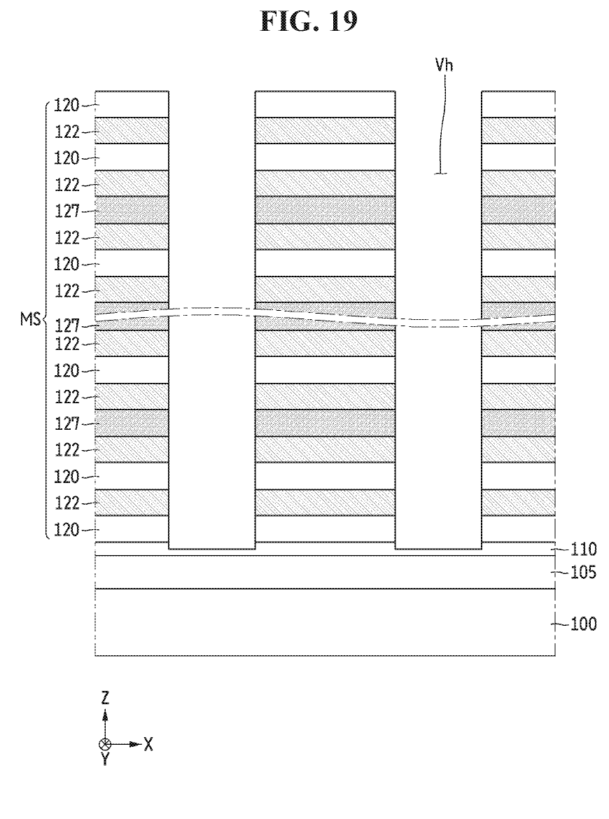

Referring to FIG. 19, vertical holes Vh are formed in the mold structure MS.

The vertical holes Vh may extend in the first direction Z and penetrate the mold structure MS. A plurality of vertical holes Vh may be arranged in a two-dimensional pattern in the plane intersecting the first direction Z (e.g., the XY plane). For example, in the plane intersecting the first direction (Z) (e.g., the XY plane), the plurality of vertical holes Vh may be arranged in various patterns, such as a lattice or honeycomb structure. The vertical holes Vh may not penetrate the etch stop layer 110. The etch stop layer 110 may protect the lower structure 105 from the etching process for forming the vertical holes Vh.

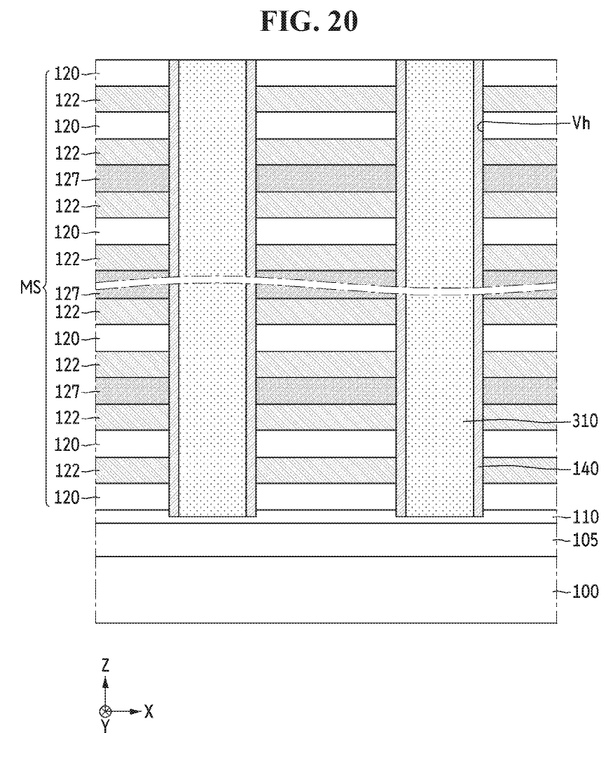

Referring to FIG. 20, the semiconductor layer 140 and the first sacrificial pattern 310 are formed in the vertical hole Vh.

For example, the semiconductor layer 140 may extend conformally along the profile of the inner side surface of the vertical hole Vh. The first sacrificial pattern 310 may fill the remaining region of the vertical hole Vh after the semiconductor layer 140 is filled.

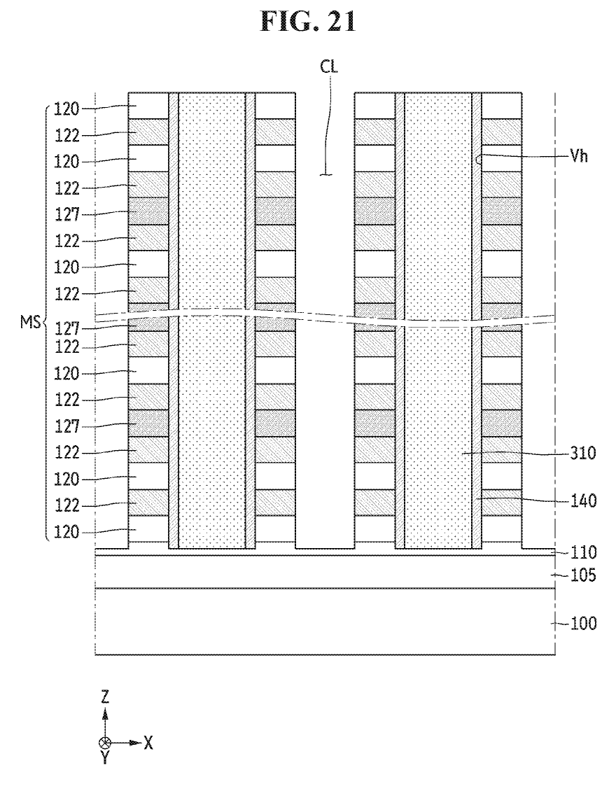

Referring to FIG. 21, a cutting region CL is formed.

The cutting region CL may extend lengthwise in the third direction Y to cut the mold structure MS. A plurality of cutting regions CL may be spaced apart from each other and arranged in the second direction X. The cutting regions CL may not cut the etch stop layer 110. The etch stop layer 110 may protect the lower structure 105 from the etching process for forming the cutting region CL.

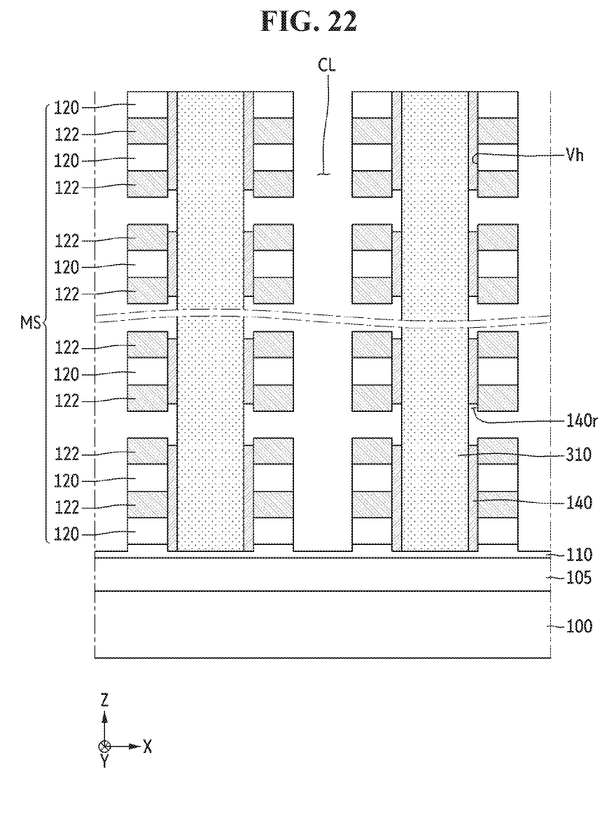

Referring to FIG. 22, a plurality of isolation sacrificial layers 127 are removed.

For example, the plurality of isolation sacrificial layers 127 exposed in the cutting region CL may be selectively removed. After the isolation sacrificial layers 127 are removed, a portion of the semiconductor layer 140 exposed due to the removal of the isolation sacrificial layers 127 may be removed. Accordingly, the semiconductor layer 140 may form a plurality of semiconductor patterns that are spaced apart from each other in the first direction Z. In some implementations, during the process of removing a portion of the semiconductor layer 140, the semiconductor layer 140 may be recessed inward more than the conductive patterns 130 to form a recess 140r.

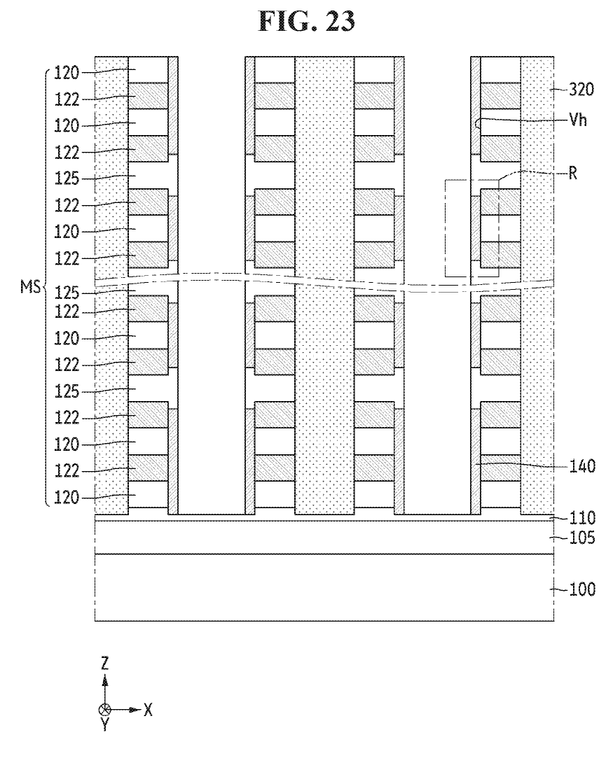

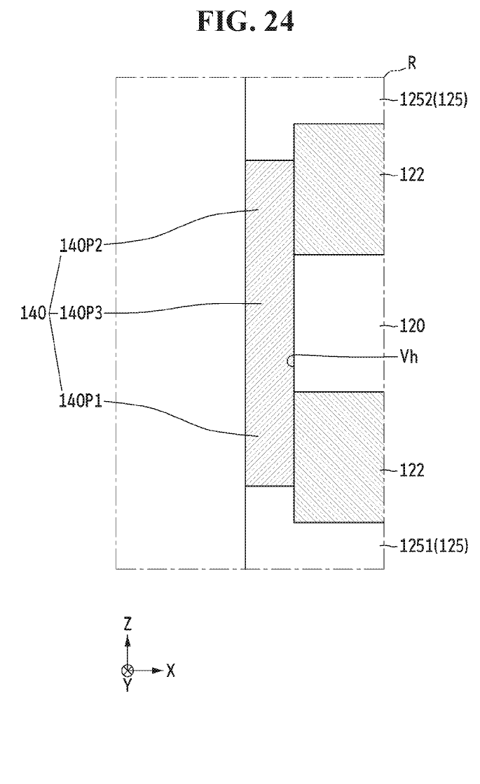

Referring to FIGS. 23 and 24, a plurality of isolation insulating layers 125 and a second sacrificial pattern 320 are formed. For reference, FIG. 24 is an enlarged view for explaining the region R in FIG. 23.

The isolation insulating layers 125 may replace a portion of the semiconductor layer 140 and the region from which the isolation sacrificial layers 127 have been removed. Through this, the semiconductor layer 140 may form a plurality of semiconductor patterns that are cut by the isolation insulating layers 125 in the first direction Z.

The second sacrificial pattern 320 may fill the cutting region CL. After the second sacrificial pattern 320 is formed, the first sacrificial pattern 310 in FIG. 22 may be selectively removed.

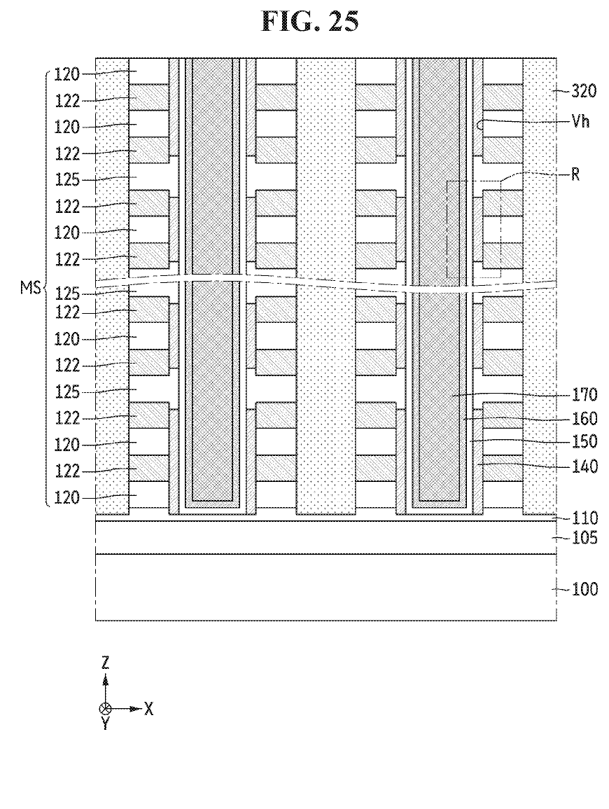

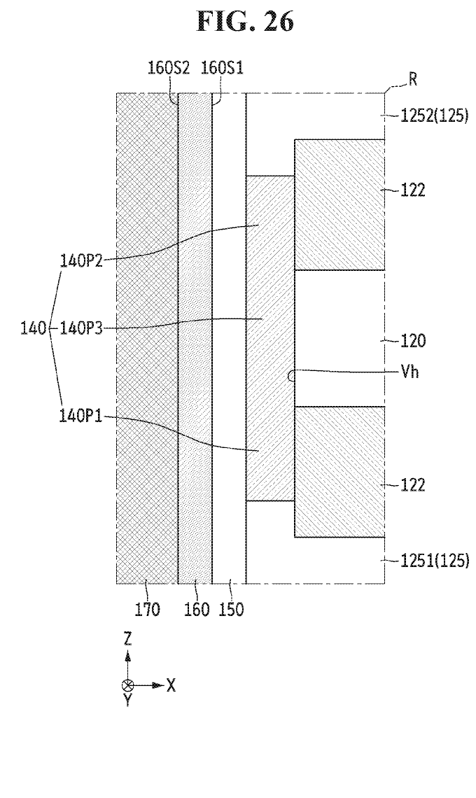

Referring to FIGS. 25 and 26, the fixed charge layer 150, the ferroelectric layer 160, and the conductive pillar 170 are formed in the vertical hole Vh. For reference, FIG. 26 is an enlarged view for explaining the region R in FIG. 25.

For example, the fixed charge layer 150 may extend conformally along the profile of the inner side surface of the semiconductor layer 140. The ferroelectric layer 160 may extend conformally along the profile of the inner side surface of the fixed charge layer 150. The conductive pillar 170 may fill the region of the vertical hole Vh remaining after the semiconductor layer 140, the fixed charge layer 150, and the ferroelectric layer 160 are filled.

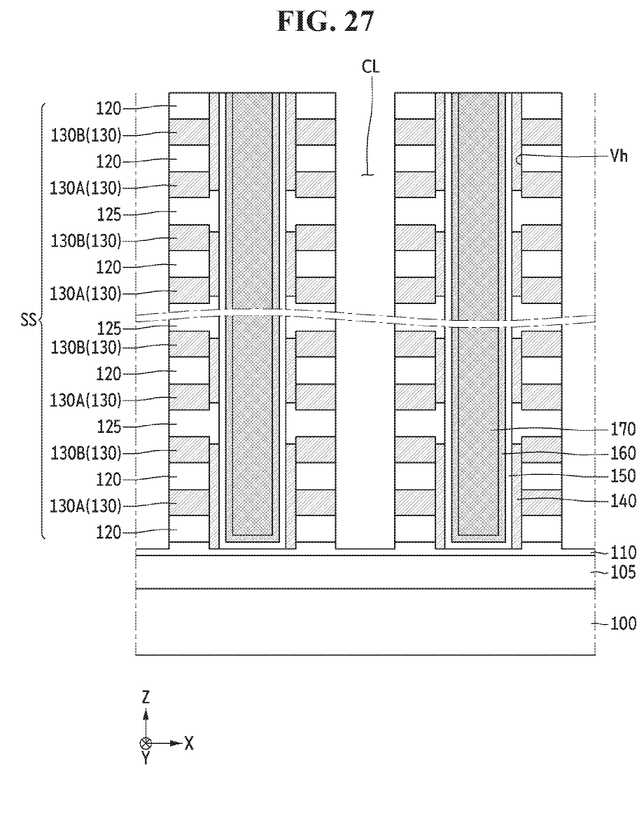

Referring to FIG. 27, a plurality of conductive patterns 130 are formed.

The plurality of conductive patterns 130 may at least partially replace the plurality of mold sacrificial layers 122. For example, the second sacrificial pattern 320 in FIG. 26 may be selectively removed. Accordingly, the mold sacrificial layers 122 in FIG. 26 that are exposed from the cutting region CL may be selectively removed. Subsequently, conductive patterns 130 may be formed to replace the regions where the mold sacrificial layers 122 were removed. Through this process, the stacked structure SS including the plurality of mold insulating layers 120, the plurality of isolation insulating layers 125, and the plurality of conductive patterns 130 may be formed.

Subsequently, referring to FIG. 3, the cutting pattern 180, the upper insulating layer 200, the contact 205, and the wiring pattern 210 may be formed. Through this process, the above-described semiconductor memory device may be fabricated using FIGS. 1 to 7.

According to an aspect of the present disclosure, there is provided a method for fabricating a semiconductor memory device comprising forming a stacked structure on a substrate, including a plurality of conductive patterns spaced apart from each other and stacked along a first direction intersecting an upper surface of the substrate, forming a vertical hole extending in the first direction within the stacked structure, forming a conductive pillar intersecting the plurality of conductive patterns within the vertical hole, forming a semiconductor layer, a ferroelectric layer, and a fixed charge layer between each of the conductive patterns and the conductive pillar, wherein, the semiconductor layer includes an n-type semiconductor material layer, the ferroelectric layer includes a first side surface facing the semiconductor layer and a second side surface facing the conductive pillar, and the fixed charge layer applies an electric field to the ferroelectric layer in a direction from the first side surface to the second side surface.

While this specification contains many specific implementation details, these should not be construed as limitations on the scope of any invention or on the scope of what may be claimed, but rather as descriptions of features that may be specific to particular implementations of particular inventions. Certain features that are described in this specification in the context of separate implementations can also be implemented in combination in a single implementation. Conversely, various features that are described in the context of a single implementation can also be implemented in multiple implementations separately or in any suitable subcombination. Moreover, although features may be described above as acting in certain combinations, one or more features from a combination can in some cases be excised from the combination, and the combination may be directed to a subcombination or variation of a subcombination.

In concluding the detailed description, those skilled in the art will appreciate that many variations and modifications may be made to the preferred implementations without substantially departing from the principles of the present disclosure. Therefore, the disclosed preferred implementations of the disclosure are used in a generic and descriptive sense only and not for purposes of limitation.

What is claimed is:

1. A semiconductor memory device comprising:
a substrate;
a stacked structure on the substrate, wherein the stacked structure includes a plurality of conductive patterns spaced apart from each other and stacked along a first direction that intersects an upper surface of the substrate;
a conductive pillar extending in the first direction and intersecting the plurality of conductive patterns;
a semiconductor layer between each conductive pattern of the plurality of conductive patterns and the conductive pillar, wherein the semiconductor layer is doped with n-type impurities; and
a ferroelectric layer between the conductive pillar and the semiconductor layer,
wherein, the ferroelectric layer is configured to exhibit a polarization-voltage hysteresis curve that has a first coercive voltage having a positive value and a second coercive voltage smaller than the first coercive voltage, and
wherein an absolute value of the first coercive voltage is greater than an absolute value of the second coercive voltage.

2. The semiconductor memory device of claim 1, wherein the second coercive voltage has a negative value.

3. The semiconductor memory device of claim 1, wherein the absolute value of the first coercive voltage is approximately 2 times to approximately 100 times the absolute value of the second coercive voltage.

4. The semiconductor memory device of claim 1, wherein, the polarization-voltage hysteresis curve has a first remanent polarization having a positive value and a second remanent polarization having a negative value, and
wherein an absolute value of the first remanent polarization is smaller than an absolute value of the second remanent polarization.

5. The semiconductor memory device of claim 4, wherein the second coercive voltage has a negative value.

6. The semiconductor memory device of claim 1, wherein the ferroelectric layer comprises a first side surface facing the semiconductor layer and a second side surface facing the conductive pillar, and
comprises a fixed charge layer having a positive charge on the first side surface of the ferroelectric layer.

7. The semiconductor memory device of claim 1, wherein the plurality of conductive patterns comprise a first conductive pattern and a second conductive pattern spaced apart from each other, and
wherein the semiconductor layer connects the first conductive pattern and the second conductive pattern and wherein the semiconductor layer does not include a PN junction.

8. A semiconductor memory device comprising:
a substrate;
a stacked structure on the substrate, wherein the stacked structure includes a plurality of conductive patterns spaced apart from each other and stacked along a first direction that intersects an upper surface of the substrate;
a conductive pillar extending in the first direction and intersecting the plurality of conductive patterns;
a semiconductor layer doped between each conductive pattern of the plurality of conductive patterns and the conductive pillar, wherein the semiconductor layer is doped with n-type impurities,
a ferroelectric layer between the conductive pillar and the semiconductor layer, wherein the ferroelectric layer comprises a first side surface facing the semiconductor layer and a second side surface facing the conductive pillar; and
a fixed charge layer on a side surface of the conductive pillar, wherein the fixed charge layer is configured to apply an electric field to the ferroelectric layer in a direction from the first side surface toward the second side surface.

9. The semiconductor memory device of claim 8, wherein the fixed charge layer is between the semiconductor layer and the ferroelectric layer.

10. The semiconductor memory device of claim 9, comprising:
an electric field induction layer between the semiconductor layer and the fixed charge layer,
wherein an electron affinity of the electric field induction layer is greater than an electron affinity of the ferroelectric layer, or an oxygen affinity of the electric field induction layer is greater than an oxygen affinity of the ferroelectric layer.

11. The semiconductor memory device of claim 9, comprising:
an electric field induction layer spaced apart from the fixed charge layer,
wherein the semiconductor layer is between the fixed charge layer and the electric field induction layer, and
wherein an electron affinity of the electric field induction layer is greater than an electron affinity of the ferroelectric layer, or an oxygen affinity of the electric field induction layer is greater than an oxygen affinity of the ferroelectric layer.

12. The semiconductor memory device of claim 8, wherein the semiconductor layer is between the ferroelectric layer and the fixed charge layer.

13. The semiconductor memory device of claim 8, wherein the ferroelectric layer is configured to exhibit a polarization-voltage hysteresis curve having a first coercive voltage that is a positive value and a second coercive voltage that is less than the first coercive voltage, and
an absolute value of the first coercive voltage is greater than an absolute value of the second coercive voltage.

14. The semiconductor memory device of claim 8, wherein the plurality of conductive patterns comprise a first conductive pattern and a second conductive pattern spaced apart from each other in the first direction, and
wherein the semiconductor layer connects the first conductive pattern and the second conductive pattern and wherein the semiconductor layer does not include a PN junction.

15. The semiconductor memory device of claim 14, wherein the conductive pillar extends in the first direction and penetrates through the first conductive pattern and the second conductive pattern.

16. The semiconductor memory device of claim 8, wherein each conductive pattern of the plurality of conductive patterns includes a first conductive pattern and a second conductive pattern spaced apart from each other in a second direction intersecting the first direction, and
wherein the semiconductor layer connects the first conductive pattern and the second conductive pattern and wherein the semiconductor layer does not include a PN junction.

17. The semiconductor memory device of claim 16, wherein the first conductive pattern and the second conductive pattern each extend in a third direction intersecting the first direction and the second direction.

18. A semiconductor memory device comprising:
a substrate;
a stacked structure on the substrate, wherein the stacked structure includes a plurality of conductive patterns spaced apart from each other and stacked along a first direction that intersects an upper surface of the substrate;
a conductive pillar extending in the first direction and intersecting the plurality of conductive patterns;
a semiconductor layer between each conductive pattern of the plurality of conductive patterns and the conductive pillar, wherein the semiconductor layer is doped with n-type impurities;
a ferroelectric layer between the conductive pillar and the semiconductor layer, wherein the ferroelectric layer includes a first side surface facing the semiconductor layer and a second side surface facing the conductive pillar; and
a fixed charge layer having a positive charge on the first side surface of the ferroelectric layer,
wherein the plurality of conductive patterns include a first conductive pattern and a second conductive pattern spaced apart from each other in the first direction, and
wherein the semiconductor layer connects the first conductive pattern and the second conductive pattern and wherein the semiconductor layer does not include a PN junction.

19. The semiconductor memory device of claim 18, wherein the stacked structure comprises a first isolation insulating layer dividing the semiconductor layer on a lower surface of the first conductive pattern, and a second isolation insulating layer dividing the semiconductor layer on an upper surface of the second conductive pattern.

20. The semiconductor memory device of claim 19, wherein, in a second direction intersecting the first direction, a portion of the first isolation insulating layer is between the conductive pillar and the first conductive pattern, and a portion of the second isolation insulating layer is between the conductive pillar and the second conductive pattern.
